(19) United States
(12) Patent Application Publication
(10) Pub. No.: US 2025/0020727 A1
(43) Pub. Date: Jan. 16, 2025

(54) METHOD AND APPARATUS FOR DETECTING INTERNAL RESISTANCE OF SECONDARY BATTERY, AND ELECTRONIC DEVICE

(71) Applicant: Ningde Amperex Technology Limited, Ningde (CN)

(72) Inventors: Yingjie CHEN, Ningde (CN); Guoda HE, Ningde (CN); Guoquan CAI, Ningde (CN)

(73) Assignee: Ningde Amperex Technology Limited, Ningde (CN)

(21) Appl. No.: 18/899,413

(22) Filed: Sep. 27, 2024

Related U.S. Application Data
(63) Continuation of application No. PCT/CN2023/084020, filed on Mar. 27, 2023.

(30) Foreign Application Priority Data
Mar. 29, 2022 (CN) 202210319702.0

(51) Int. Cl. G01R 31/389; G01R 31/367; G01R 31/392; H01M 10/48

(52) U.S. Cl. CPC G01R 31/389; G01R 31/367; G01R 31/392; H01M 10/482

(57) ABSTRACT

A method for detecting an internal resistance of a secondary battery, and an electronic device. The method for detecting an internal resistance of a secondary battery includes: charging a secondary battery with a charge current, and in response to a real-time state of charge (SOC) of the secondary battery reaching a target SOC value, stopping charging the secondary battery and keeping for a first duration t; and obtaining data related to the secondary battery during a charge period and a charge stopping period of the secondary battery, and determining the internal resistance of the secondary battery on the basis of the data related to the secondary battery, where the target SOC value includes a plurality of values.

### CROSS-REFERENCE TO RELATED APPLICATIONS

This application is a continuation application of International Patent Application Serial Number PCT/CN2023/084020, filed on Mar. 27, 2023, which claims priority to Chinese Patent Application No. 202210319702.0, filed on Mar. 29, 2022 and entitled “METHOD AND APPARATUS FOR DETECTING INTERNAL RESISTANCE OF SECONDARY BATTERY, AND ELECTRONIC DEVICE”, which are incorporated herein by reference in its entirety.

### TECHNICAL FIELD

This application belongs to the technical field of battery testing, and particularly relates to a method and apparatus for detecting an internal resistance of a secondary battery, and an electronic device.

### BACKGROUND

A direct current internal resistance of a secondary battery is usually obtained by a battery testing apparatus through offline testing before the battery is put into use. However, as the service time of the secondary battery increases, the direct current internal resistance thereof changes correspondingly. If the battery state is still preset and analyzed according to the direct current internal resistance obtained through offline testing, the accuracy of battery analysis will be reduced.

### SUMMARY

Embodiments of this application provide a method and apparatus for detecting an internal resistance of a secondary battery, and an electronic device, so as to test a direct current internal resistance of the secondary battery online, thereby improving the accuracy of battery analysis.

According to a first aspect, embodiments of this application provide a method for detecting an internal resistance of a secondary battery. The method includes: step S1, charging the secondary battery with a charge current, and in response to a real-time state of charge (SOC) of the secondary battery reaching a target SOC value, stopping charging the secondary battery and keeping for a first duration t; and step S2, obtaining data related to the secondary battery during a charge period and a charge stopping period of the secondary battery, and determining the internal resistance of the secondary battery on the basis of the data related to the secondary battery, where the target SOC value includes a plurality of values.

Optionally, in case of different target SOC values, when the secondary battery is charged, in response to the real-time SOC value of the secondary battery reaching any target SOC value, step S1 and step S2 are performed to determine the internal resistance of the secondary battery corresponding to the target SOC value.

Optionally, a target SOC value is determined on the basis of an equivalent cycle number of the secondary battery, where the equivalent cycle number N of the secondary battery is determined in one of the following manners:

$$N = \frac{( \begin{matrix}cumulative charge capacity + \\ cumulative discharge capacity\end{matrix} ) / 2}{nominal capacity} , \qquad a1 )$$

where N is an integer, and
b1) N=cumulative charge capacity×h, where h is an ageing coefficient of the secondary battery, 0.75≤h≤0.95, and N is an integer.

Optionally, the target SOC value includes M target values, and the determining the target SOC value on the basis of an equivalent cycle number of the secondary battery includes: dividing the equivalent cycle number N of the secondary battery by M to obtain a remainder R, and determining the target SOC value SOC_{cal} according to the following formula:

$${SOC}_{cal} = \frac{R}{M} \times 100 \% ,$$

where 2≤M≤50, and M is an integer.

Optionally, the target SOC value is determined on the basis of an adjustment coefficient b, where the target SOC value SOC_{cal}∈[SOC_{cal}−b, SOC_{cal}+b], and 0≤b≤10%.

Optionally, the target SOC value includes 0% and 100%.

Optionally, the internal resistance of the secondary battery includes at least one of a direct current internal resistance R1, an ohmic impedance R2, and a polarization impedance R3.

Optionally, the data related to the secondary battery includes: a charge current I and a terminal voltage V1 of the secondary battery when the secondary battery stops being charged, and a terminal voltage V0 when the secondary battery stops being charged and is kept for the first duration, where R1=(V1−V0)/I; or the data related to the second battery includes: a charge current I and a terminal voltage V1 of the secondary battery when the secondary battery stops being charged, and a terminal voltage V2 when the secondary battery stops being charged and begins to be polarized, where R2=(V1−V2)/I; or the data related to the secondary battery includes: terminal voltages of the secondary battery corresponding to different moments within the first duration t, an open-circuit voltage of the secondary battery corresponding to the target SOC value, a terminal voltage when the secondary battery stops being charged and begins to be polarized, and the polarization impedance R3 obtained on the basis of a least square method.

Optionally, the state of charge (SOC) and/or a state of heath (SOH) of the secondary battery is determined on the basis of internal resistances of the secondary battery corresponding to the different target SOC values.

Optionally, a direct current internal resistance increase rate of a battery pack is determined on the basis of internal resistances of the secondary battery corresponding to the different target SOC values, where the direct current internal resistance increase rate of the battery pack is a ratio of a current direct current internal resistance of the battery pack to an initial direct current internal resistance of the battery pack. The battery pack includes a plurality of the secondary batteries, and the initial direct current internal resistance of the battery pack is an average direct current internal resistance of the battery pack after a cycles, where 0≤a≤10.

Optionally, the current direct current internal resistance R1_{pack} of the battery pack meets the following formula:

$$R {1}_{pack} = \frac{{\sum }_{i = 1}^{n} R {1}^{′}}{n} ,$$

where n represents the number of secondary batteries. R1′ represents an average value of direct current internal resistances corresponding to different target SOC values, and R1′ satisfies the following formula:

$$R {1}^{′} = \frac{{\sum }_{soc = 0}^{100 \%} R 1}{m} ,$$

where m represents the number of different target SOC values, and R1 represents direct current internal resistances corresponding to different target SOC values.

According to a second aspect, embodiments of this application provide an apparatus for detecting an internal resistance of a secondary battery. The apparatus includes: a control unit, configured to charge a secondary battery with a charge current, and in response to a real-time state of charge (SOC) of the secondary battery reaching a target SOC value, stop charging the secondary battery and keep for a first duration t; and a calculation unit, configured to obtain data related to the secondary battery during a charge period and a charge stopping period of the secondary battery, and determine an internal resistance of the secondary battery on the basis of the data related to the secondary battery, where the target SOC value includes a plurality of values.

Optionally, the apparatus may further include an execution unit, configured to in case of different target SOC values, when the secondary battery is charged, in response to the real-time SOC value of the secondary battery reaching any target SOC value, determine the internal resistance of the secondary battery corresponding to the target SOC value through the control unit and the calculation unit.

Optionally, the apparatus may further include a first determining unit, configured to determine a target SOC value on the basis of an equivalent cycle number of the secondary battery, where the equivalent cycle number N of the secondary battery is determined in one of the following manners:

$$N = \frac{( \begin{matrix}cumulative charge capacity + \\ cumulative discharge capacity\end{matrix} ) / 2}{nominal capacity} , \qquad a 1 )$$

where N is an integer, and
b1) N=cumulative charge capacity×h, where h is an ageing coefficient of the secondary battery, 0.75≤h≤0.95, and N is an integer.

Optionally, the target SOC value may include M target values, and the first determining unit may include a calculation subunit, configured to divide the equivalent cycle number N of the secondary battery by M to obtain a remainder R, and determine the target SOC value SOC_{cal} according to the following formula:

$${SOC}_{cal} = \frac{R}{M} \times 100 \% ,$$

where 2≤M≤50, and M is an integer.

Optionally, the apparatus may further include a second determining unit, configured to determine the target SOC value on the basis of an adjustment coefficient b, where the target SOC value SOC_{cal}∈[SOC_{cal}−b,SOC_{cal}+b], and 0≤b≤10%.

Optionally, the target SOC value includes 0% and 100%.

Optionally, the internal resistance of the secondary battery includes at least one of a direct current internal resistance R1, an ohmic impedance R2, and a polarization impedance R3.

Optionally, the data related to the secondary battery may include: a charge current I and a terminal voltage V1 of the secondary battery when the secondary battery stops being charged, and a terminal voltage V0 when the secondary battery stops being charged and is kept for the first duration, where R1=(V1−V0)/I; or the data related to the second battery includes: a charge current I and a terminal voltage V1 of the secondary battery when the secondary battery stops being charged, and a terminal voltage V2 when the secondary battery stops being charged and begins to be polarized, where R2=(V1−V2)/I; or the data related to the secondary battery includes: terminal voltages of the secondary battery corresponding to different moments within the first duration t, an open-circuit voltage of the secondary battery corresponding to the target SOC value, a terminal voltage when the secondary battery stops being charged and begins to be polarized, and the polarization impedance R3 obtained on the basis of a least square method.

Optionally, the apparatus may further include a third determining unit, configured to determine the state of charge (SOC) and/or an SOH of the secondary battery on the basis of internal resistances of the secondary battery corresponding to the different target SOC values.

Optionally, the apparatus may further include a third determining unit, configured to determine a direct current internal resistance increase rate of a battery pack on the basis of internal resistances of the secondary battery corresponding to the different target SOC values, where the direct current internal resistance increase rate of the battery pack is a ratio of a current direct current internal resistance of the battery pack to an initial direct current internal resistance of the battery pack. The battery pack includes a plurality of the secondary batteries, and the initial direct current internal resistance of the battery pack is an average direct current internal resistance of the battery pack after a cycles, where 0≤a≤10.

Optionally, the current direct current internal resistance R1_{pack} of the battery pack meets the following formula:

$$R {1}_{pack} = \frac{{\sum }_{i = 1}^{n} R {1}^{′}}{n} ,$$

where n represents the number of secondary batteries. R1′ represents an average value of direct current internal resistances corresponding to different target SOC values, and R1′ satisfies the following formula,

$$R {1}^{′} = \frac{{\sum }_{s oc = 0}^{100 \%} R 1}{m} ,$$

where m represents the number of different target SOC values, and R1 represents direct current internal resistances corresponding to different target SOC values.

According to a third aspect, embodiments of this application provide a battery pack, including a plurality of battery cells and a processor, where the processor detects internal resistances of the battery cells and/or a direct current internal resistance of the battery pack by using the method for detecting an internal resistance of a secondary battery according to the first aspect.

According to a fourth aspect, embodiments of this application provide an electrical device. The electrical device includes an electrical main body and the battery pack according to the third aspect. The battery pack is configured to supply power to the electrical main body.

According to a fifth aspect, embodiments of this application provide a program product. When instructions in the program product are executed by a processor of an electronic device, the electronic device can perform the method for detecting an internal resistance of a secondary battery according to the first aspect.

According to the method and apparatus for detecting an internal resistance of a secondary battery, the battery pack, the electrical device and the program product as provided in embodiments of this application, the secondary battery is charged with the charge current, and in response to the real-time state of charge (SOC) of the secondary battery reaching the target SOC value, the secondary battery stops being charged and is kept for the first duration t; and data related to the secondary battery during a charge period and a charge stopping period of the secondary battery is obtained, and the internal resistance of the secondary battery is determined on the basis of the data related to the secondary battery, where the target SOC value includes the plurality of values. In this way, the direct current internal resistance of the secondary battery can be tested online, so that the accuracy of battery analysis is improved.

### BRIEF DESCRIPTION OF DRAWINGS

To describe technical solutions of embodiments of this application more clearly, the following outlines the drawings to be used in embodiments of this application. A person of ordinary skill in the art may derive other drawings from the drawings without making any creative efforts.

FIG. 1 is a schematic flow diagram of a method for detecting an internal resistance of a secondary battery according to an embodiment of this application.

FIG. 2 is a schematic diagram of a curve for terminal voltage collection results in the method for detecting an internal resistance of a secondary battery according to an embodiment of this application.

FIG. 3 is a schematic diagram of a correlation curve for terminal voltage collection results and calculation results in the method for detecting an internal resistance of a secondary battery according to an embodiment of this application.

FIG. 4 is a schematic diagram of a correlation curve for terminal voltage collection results and calculation results in the method for detecting an internal resistance of a secondary battery according to an embodiment of this application.

FIG. 5 is a schematic diagram of a correlation curve for terminal voltage collection results and calculation results in the method for detecting an internal resistance of a secondary battery according to an embodiment of this application.

FIG. 6 is a schematic diagram of a correlation curve for terminal voltage collection results and calculation results in the method for detecting an internal resistance of a secondary battery according to an embodiment of this application.

FIG. 7 is a schematic diagram of a curve for ohmic impedances in the method for detecting an internal resistance of a secondary battery according to an embodiment of this application.

FIG. 8 is a schematic structural diagram of an apparatus for detecting an internal resistance of a secondary battery according to an embodiment of this application.

FIG. 9 is a schematic structural diagram of a battery management system according to still another embodiment of this application.

### DETAILED DESCRIPTION

The following describes features and exemplary embodiments in detail of each aspect of this application. To make the objectives, technical solutions, and advantages of this application clearer, the following describes this application in further detail with reference to drawings and specific embodiments. It is to be understood that specific embodiments described herein are merely intended to interpret this application rather than to limit this application. A person skilled in the art can implement this application without some of the specific details. The following description of embodiments is merely intended to provide a better understanding of this application by showing examples of this application.

It should be noted that the relational terms such as “first” and “second” herein are only used to distinguish one entity or operation from another entity or operation, and do not necessarily require or imply that there is any such actual relationship or order between these entities or operations. In addition, the terms “comprise”, “include”, or any other variations thereof are intended to cover non-exclusive inclusions, such that a process, method, article or apparatus including a series of elements not only includes these elements, but also includes other elements which are not expressly listed, or further includes elements which are inherent to such process, method, article or apparatus. Without more constraints, an element preceded by “includes . . . ” does not preclude the presence of other identical elements in the process, method, article, or apparatus that includes the element.

To solve the problems in the prior art, embodiments of this application provide a method and apparatus for detecting an internal resistance of a secondary battery, a battery pack, an electrical device and a program product. The following will first describe the method for detecting an internal resistance of a secondary battery as provided in embodiments of this application.

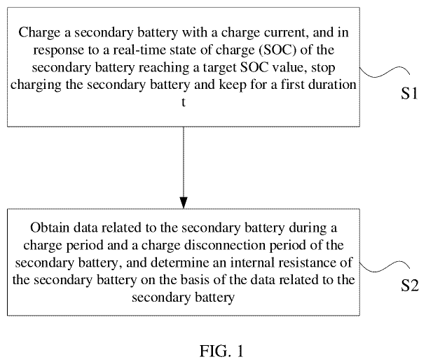

FIG. 1 shows a schematic flow diagram of a method for detecting an internal resistance of a secondary battery according to an embodiment of this application. As shown in FIG. 1, the method includes the following steps:
Step S1, Charging a secondary battery with a charge current, and in response to a real-time state of charge (SOC) of the secondary battery reaching a target SOC value, stopping charging the secondary battery and keeping for a first duration t.
Step S2, Obtaining data related to the secondary battery during a charge period and a charge stopping period of the secondary battery, and determining an internal resistance of the secondary battery on the basis of the data related to the secondary battery.

The secondary battery may be a lithium battery or a sodium battery, etc. Optionally, the method for detecting an internal resistance of a secondary battery as provided in embodiments of this application is executed by a processor in a battery pack. For example, it may be implemented by a microcontroller unit (MCU) on a circuit board of a battery management system (BMS) and a program stored in a flash, that is, various steps of the embodiments of this application may be executed by the BMS. The circuit board of the BMS is a component of the battery pack.

During the process of charging the secondary battery with the charge current, the charge current can be cut off once or several times to create a condition of intermittent charging, so that the internal resistance (the internal resistance may include at least one of a direct current internal resistance R1, an ohmic impedance R2, and a polarization impedance R3) of the secondary battery can be calculated on the basis of the data related to the secondary battery obtained each time the charge current is cut off.

The time to cut off the charge current mentioned herein may be the moment when the real-time state of charge (SOC) of the secondary battery reaches the target SOC value, that is, when the current real-time SOC value reaches the target SOC value, the charge current is cut off.

The target SOC value is a set value and may include a plurality of values, that is, the charge current may be cut off multiple times. The plurality of target SOC values may be different. For different target SOC values, when the secondary battery is charged, in response to the real-time SOC value of the secondary battery reaching any target SOC value, step S1 and step S2 are performed to determine the internal resistance of the secondary battery corresponding to any target SOC value. That is, every time when the real-time SOC value reaches any target SOC value, the secondary battery stops being charged and is kept for the first duration t, then data related to the secondary battery during a charge period and a charge stopping period of the secondary battery is obtained, and the internal resistance of the secondary battery is determined on the basis of the data related to the secondary battery.

In one embodiment, the measurement of a plurality of target SOC values may be implemented in different charge and discharge cycles. That is, within each charge and discharge cycle, instead of detecting all the target SOC values within one charge and discharge cycle, it is possible to detect only the internal resistance corresponding to one or part of the target SOC values. This can reduce the impact of each internal resistance test on the normal use of the battery and avoid the situation that charge is stopped multiple times in a charge and discharge cycle. In this way, as much internal resistance data as possible can be obtained through simple online testing steps, and the complex testing process in the related art can be simplified.

Optionally, an internal resistance data table can be updated once every time when the internal resistance of at least one target SOC value (the specific value can be set according to the situation, which is not limited in the embodiments of this application) is tested. The internal resistance data table is used to represent internal resistance data corresponding to different SOC values.

Optionally, the setting of the target SOC value can be determined on the basis of an equivalent cycle number of the secondary battery, where the equivalent cycle number N of the secondary battery is determined in one of the following manners:

$$N = \frac{( cumu l ative charge capacity + cumulative discharge capacity ) / 2}{nominal capacity} , \qquad a 1 )$$

where N is an integer.

In the formula, cumulative charge capacity+cumulative discharge capacity is equal to the total sum of charge capacity and discharge capacity.

For example, assuming that the nominal capacity is 10 Ah, corresponding to the rated capacity of a battery cell, that is, the capacity of the battery cell at an SOC of 100%, when the cumulative discharge capacity is 28 Ah and the cumulative charge capacity is 30 Ah, the calculation result is 2.9, and the equivalent cycle number after rounding is 2 (cycles).
b1) N=cumulative charge capacity×h, where h is an ageing coefficient of the secondary battery, 0.75≤h≤0.95, and N is an integer.

When battery cell ageing is taken into account, the ageing coefficient h can be used in this multiplication formula. The ageing coefficient h can be 0.75 to 0.9, where the ageing coefficient of 0.75 corresponds to an SOH of 50%, and the SOH of 50% indicates that the capacity of the battery cell at this moment is 50% of the nominal capacity.

The target SOC value may include M target values. Further, the determining the target SOC value on the basis of the equivalent cycle number of the secondary battery may include dividing the equivalent cycle number N of the secondary battery by M to obtain a remainder R, and determining the target SOC value SOC_{cal} according to the following formula:

$${SOC}_{c a l} = \frac{R}{M} \times 100 \% ;$$

where, 2≤M≤50, and M is an integer.

That is, after the equivalent cycle number N of the secondary battery is determined, the percentage of the ratio of the remainder R obtained by dividing N by the preset value M to M is taken as the target SOC value.

For example, assuming M is 10, if N=15, then R=5, and the target SOC value

$${SOC}_{c a l} = \frac{5}{10} \times 100 \% = 50 \% ;$$

and if N=10, then R=0 or 10, and the target SOC value SOC_{cal}=0% or 100%.

For another example, when M is 8, the target SOC values corresponding to N=8 to 15 are 0% and 100%, 12.5%, 25%, 37.5%, 50%, 62.5%, 75%, and 87.5%, respectively.

Every time when the real-time SOC value reaches the target SOC value, the charge is stopped and a calculation of the internal resistance is triggered. The magnitude of the charge current can be adjusted every time when charge is stopped. The magnitude of the charge current is determined according to the characteristics of a charger. In case of a smart charger, the magnitude of the charging current can be adjusted, so that the internal resistance can be detected at multiple different charge rates.

Optionally, the target SOC value may also be adjusted on the basis of an adjustment coefficient b, and the adjusted SOC value may be used as the final target SOC value. For example, the target SOC value SOC_{cal}∈[SOC_{cal}−b,SOC_{cal}+b], and 0≤b≤10%. Optionally, two endpoints within the range of [SOC_{cal}−b, SOC_{cal}+b] can be taken, i.e., SOC_{cal}−b and SOC_{cal}+b.

That is, if a target SOC value is preset, or a target SOC value is calculated according to the above optional implementation, the target SOC value can be adjusted on the basis of b, so as to detect more target SOC values, thereby achieving finer detection, or detecting a wider range of SOC values.

For example, if b is 3%, and a plurality of target SOC values are 0%, 10%, 20%, 30%, . . . , 100%, then after adjustment by b, the target SOC values may include 0%, 3%, 7%, 13%, 17%, 23%, 27%, 33%, . . . , 100%.

The above steps of determining the target SOC value can be implemented by the MCU in the BMS.

Every time when the real-time SOC value reaches the target SOC value, the charge current is cut off, the secondary battery stops being charged and is kept for the first duration t, and then charging is resumed, where the first duration t may be a set value, which is not limited in embodiments of this application. For example, it may be selected according to the actual use conditions of the battery cell and the RC time constant. The RC time constant referred herein may be defined as a time required for a polarization voltage to rebound by 66.6%, and is usually between 5 s to 20 s.

Optionally, the instruction to cut off the charge current may be given by the BMS. Specifically, the BMS may give a calculation flag bit CalFlag=1 to a bottom layer of the BMS when the real-time SOC value reaches the target SOC value, where CalFlag=1 indicates that charge is stopped. Then, after charge is stopped for the first duration t, the BMS sets the calculation flag CalFlag as 0 to indicate that charge is resumed.

When the bottom layer of the BMS receives the calculation flag bit CalFlag=1, it can perform the action of stopping charge. Specifically, the action of stopping charging may include: 1, turning off a charging and discharging Metal-Oxide-Semiconductor Field-Effect Transistor (MOSFET); 2, cutting off a relay; and 3, requesting a charge current of 0 from a smart charger. Specifically, the BMS can request a charge current of a corresponding magnitude from the smart charger through communication, and the smart charger can adjust the magnitude of the charge current. At this time, the internal resistances at multiple different charge rates can be detected by adjusting the magnitude of the charge current.

Data related to the secondary battery can be recorded before and after charge is stopped. Specifically, the related data may include the voltage and current of all battery cells. At the last moment before charge is stopped, related data at two time points can be collected, and the interval between the two time points may be set to n s, such as 1 s, which may also be 100 ms, 250 ms, etc. For example, when charge is stopped at moment t0, in addition to the charge current collected at moment t0, the charge current collected at moment (t0−1) s can also be collected.

After the data related to the secondary battery during a charge period and a charge stopping period of the secondary battery are obtained, the internal resistance of the secondary battery may be determined on the basis of the data related to the secondary battery.

The internal resistance of the secondary battery includes at least one of a direct current internal resistance R1, an ohmic impedance R2, and a polarization impedance R3.

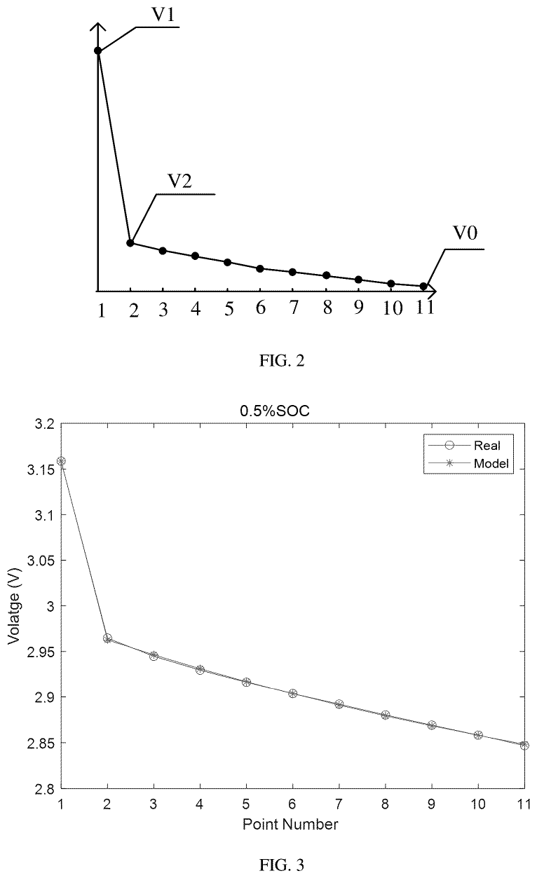

Correspondingly, when the internal resistance of the secondary battery includes direct current resistance (DCR) R1, the data related to the secondary battery may include: a charge current I and a terminal voltage V1 of the secondary battery when the secondary battery stops being charged, and a terminal voltage V0 when the secondary battery stops being charged and is kept for the first duration. FIG. 2 is a schematic diagram of a curve for terminal voltages collected from the moment when the secondary battery stops being charged until the secondary battery is kept for the first duration after charge stopping, where the x-axis represents a sampling count, the y-axis represents a voltage value of the terminal voltage, and V1 and V0 represent terminal voltages collected at a first sampling moment and a last sampling moment, respectively. direct current internal resistance R1 is calculated according to the following formula:

$$R 1 = ( V 1 - V 0 ) / I \qquad Formula 1$$

The direct current internal resistance R1 can be calculated according to the collected voltage and current.

When the internal resistance of the secondary battery includes an ohmic impedance R2, the data related to the second battery includes: a charge current I and a terminal voltage V1 of the secondary battery when the secondary battery stops being charged, and a terminal voltage V2 when the secondary battery stops being charged and begins to be polarized. Specifically, referring to FIG. 2, V2 is the corresponding terminal voltage of the battery cell 1 sampling time after charge is stopped, and also represents the initial moment when the battery cell begins to be polarized. The identification formula for the ohmic impedance R2 is as follows:

$$R 2 = ( V 1 - V 2 ) / I \qquad Formula 2$$

When the internal resistance of the secondary battery includes a polarization impedance R3, the data related to the secondary battery includes: terminal voltages of the secondary battery corresponding to different moments within the first duration t, an open-circuit voltage of the secondary battery corresponding to the target SOC value, a terminal voltage V2 when the secondary battery stops being charged and begins to be polarized, and the polarization impedance R3 which can be obtained on the basis of a least square method.

The identification formula for the polarization impedance R3 is as follows:

$$V ( {t}_{i} ) = {V}_{o c v} ( {SOC}_{c a l} ) - V 2 \times {e}^{- \frac{{t}_{i}}{τ .}} \qquad Formula 3$$

$$τ = R 3 {C}_{P} \qquad Formula 4$$

where τ represents an RC time constant, and C_{P} represents a capacitance in an RC parallel circuit; V_{ocv}(SOC_{cal}) represents an open-circuit voltage of the secondary battery corresponding to the target SOC value, and can be obtained from an SOC-OCV lookup table. The corresponding OCV queried on the basis of the target SOC value is V_{ocv}(SOC_{cal}), which is a known quantity with a constant value; V(tᵢ) is a terminal voltage of the secondary battery collected by a chip at an i-th sampling moment, and is a known quantity; and tᵢ is the i-th sampling moment. V2 represents the initial moment of polarization of the battery cell after charge is stopped. Exemplarily, referring to FIG. 2, V2 is the corresponding voltage of the battery cell collected 1 sampling time after charge is stopped.

According to the above Formulas 2, 3, and 4, the collected voltages and currents are substituted into the identification formula to form an overdetermined equation, and undetermined parameters are fitted by using the least square method, so that the unknown R2, R3, and C_{P} can be identified and the ohmic impedance R2 and polarization impedance R3 can be obtained.

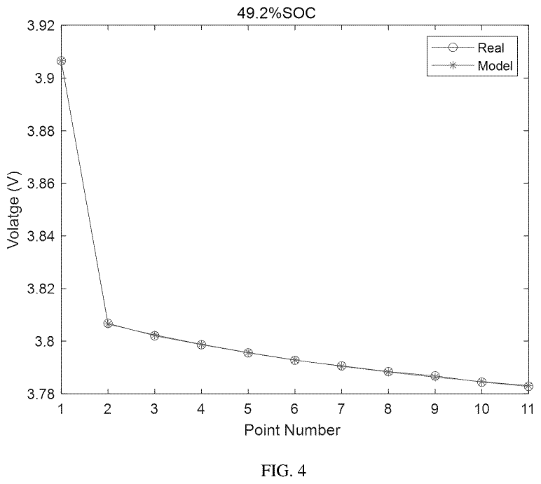

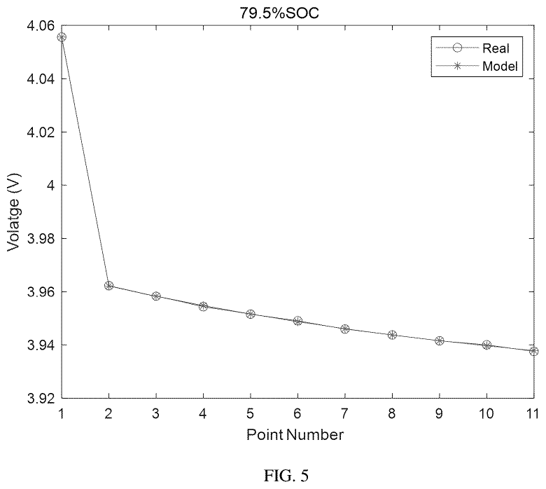

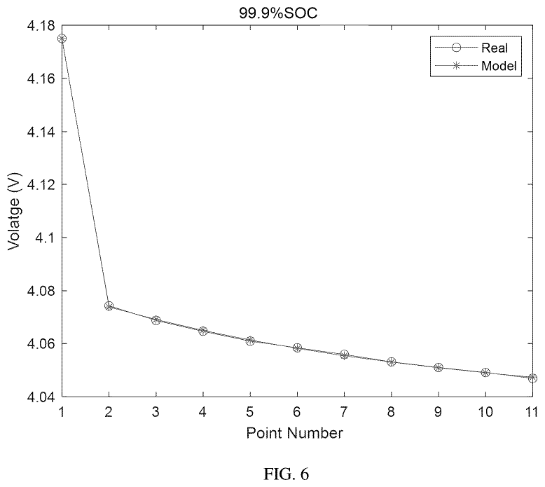

After experiments, the terminal voltage calculated by inversely substituting R3 and Cp obtained after parameter identification into Formula 3 is very close to the collected terminal voltage, and curve graphs of the two are essentially coincident. FIG. 3 to FIG. 7 respectively show curve comparison graphs of the terminal voltages V(tᵢ) collected at different sampling moments and the terminal voltages at different moments calculated on the basis of parameter identification under different target SOC values (0.5%, 49.2%, 79.5% and 99.9%, respectively). The x-axis represents a sampling point number, the y-axis represents a voltage (Voltage, at a unit of V), the curve marked by the symbol “o” is an actual sampled terminal voltage (Real), and the curve marked by the symbol “*” is a calculated terminal voltage (Model) after parameter identification. It can be seen that the curves of the two are basically coincident.

The state of charge (SOC) and/or a state of health (SOH) of the secondary battery can be determined on the basis of internal resistances of the secondary battery corresponding to the different target SOC values.

In addition, a direct current internal resistance increase rate of a battery pack can also be determined on the basis of internal resistances of the secondary battery corresponding to the different target SOC values, where the direct current internal resistance increase rate of the battery pack is a ratio of a current direct current internal resistance of the battery pack to an initial direct current internal resistance of the battery pack. The battery pack includes a plurality of the secondary batteries, and the initial direct current internal resistance of the battery pack is an average direct current internal resistance of the battery pack after a cycle, where 0≤a≤10.

Exemplarily, when a=10, internal resistance data and a resistance increase factor can be updated every 10 charge and discharge cycles. After 10 cycles of charging, the internal resistances corresponding to all target SOC values can be obtained. The internal resistances may include an ohmic impedance, a polarization impedance, and a direct current internal resistance. Calculation results of an example may refer to the internal resistance table shown below:

TABLE 1
Internal resistance table

| | | Polarization | Direct current |
|---|---|---|---|
| Target SOC | Ohmic impedance | impedance | internal resistance |
| value | (R_{d}/ohm) | (Rₚ/ohm) | (DCR/ohm) |
| 0% | 0.0134 | 0.0211 | 0.0275 |
| 10% | 0.0098 | 0.0044 | 0.0127 |
| 20% | 0.0081 | 0.0036 | 0.0105 |
| 30% | 0.0077 | 0.0031 | 0.0098 |
| 40% | 0.0075 | 0.0032 | 0.0096 |
| 50% | 0.0074 | 0.0030 | 0.0094 |
| 60% | 0.0072 | 0.0033 | 0.0094 |
| 70% | 0.0070 | 0.0037 | 0.0095 |
| 80% | 0.0068 | 0.0034 | 0.0091 |
| 90% | 0.0068 | 0.0029 | 0.0087 |
| 100% | 0.0074 | 0.0033 | 0.0096 |

Optionally, the above-mentioned internal resistance table can be measured within a certain temperature range. A plurality of temperature intervals can be divided, and an internal resistance table is detected for each temperature interval, such as an internal resistance table above 25° C., an internal resistance table at 0° C. to 25° C., and an internal resistance table at −20° C. to 0° C. The specific division is not limited. The narrower the interval, the preciser the result.

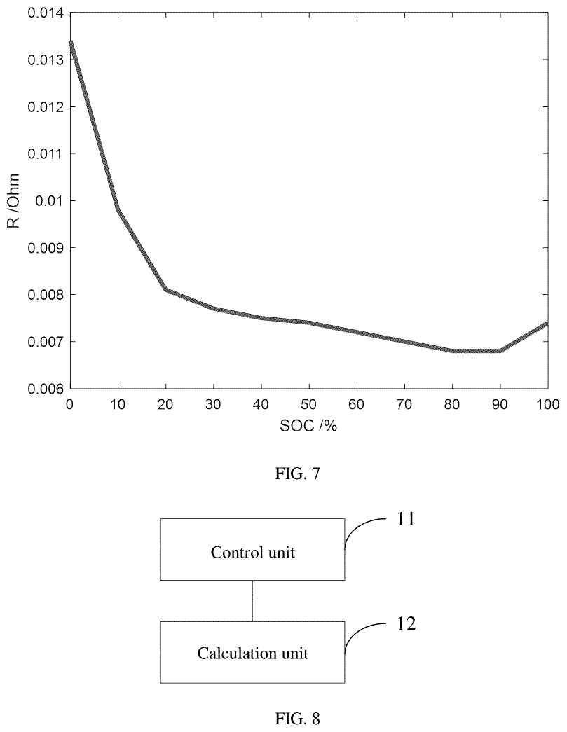

On the basis of the corresponding relationship between the ohmic impedance and the target SOC value provided in Table 1, a curve of the ohmic impedance changing with the target SOC value is prepared, as shown in FIG. 7. This is similar to the case of the polarization impedance and the direct current internal resistance, so exemplary figures for them are not provided herein.

In addition, an impedance increase factor can also be calculated. The following description can be referred to for the specific calculation process:

The current direct current internal resistance R1_{pack} of the battery pack meets the following formula:

$$R {1}_{p a c k} = \frac{{\sum }_{i = 1}^{n} R {1}^{′}}{n} ,$$

where n represents the number of secondary batteries;
where R1′ represents an average value of direct current internal resistances corresponding to different target SOC values, and R1′ satisfies the following formula:

$$R {1}^{′} = \frac{{\sum }_{s oc = 0}^{100 \%} R 1}{m} ,$$

where m represents the number of different SOC values, and R1 represents direct current internal resistances corresponding to different target SOC values.

A formula for calculating an impedance increase factor is as follows:

$$D C {R}_{i n c r e a s e} = \frac{R {1}_{p a c k} ( i )}{R {1}_{p a c k} ( 0 )}$$

The impedance increase factor DCR_{increase} is greater than or equal to 0, R1_{pack}(i) is a current equivalent direct current impedance corresponding to the i-th target SOC value of the battery pack, and R1_{pack}(0) is an equivalent direct current impedance at the initial moment of the Pack. The average value at the first 5-10 charge and discharge cycles can be taken.

FIG. 8 is a schematic structural diagram of an apparatus for detecting an internal resistance of a secondary battery according to an embodiment of this application. The apparatus for detecting an internal resistance of a secondary battery according to an embodiment of this application can be used to implement the method for detecting an internal resistance of a secondary battery according to an embodiment of this application. For the parts not detailed in the embodiments of the apparatus for detecting an internal resistance of a secondary battery according to an embodiment of this application, reference can be made to the descriptions in the embodiments of the method for detecting an internal resistance of a secondary battery according to an embodiment of this application.

As shown in FIG. 8, the apparatus for detecting an internal resistance of a secondary battery according to an embodiment of this application includes a control unit 11 and a calculation unit 12.

The control unit 11 is configured to charge a secondary battery with a charge current, and in response to a real-time state of charge (SOC) of the secondary battery reaching a target SOC value, stop charging the secondary battery and keep for a first duration t.

The calculation unit 12 is configured to obtain data related to the secondary battery during a charge period and a charge stopping period of the secondary battery, and determine an internal resistance of the secondary battery on the basis of the data related to the secondary battery.

During the process of charging the secondary battery with the charge current, the charge current can be cut off once or several times to create a condition of intermittent charging, so that the internal resistance (the internal resistance may include at least one of a direct current internal resistance R1, an ohmic impedance R2, and a polarization impedance R3) of the secondary battery can be calculated on the basis of the data related to the secondary battery obtained each time the charge current is cut off.

The time to cut off the charge current mentioned herein may be the moment when the real-time state of charge (State of Charge, SOC) of the secondary battery reaches the target SOC value, that is, when the current real-time SOC value reaches the target SOC value, the charge current is cut off.

The target SOC value is a set value and may include a plurality of values, that is, the charge current may be cut off multiple times.

Optionally, the apparatus may further include an execution unit, configured to in case of different target SOC values, when the secondary battery is charged, in response to the real-time SOC value of the secondary battery reaching any target SOC value, determine the internal resistance of the secondary battery corresponding to the target SOC value through the control unit and the calculation unit.

The plurality of target SOC values may be different. Every time when the real-time SOC value reaches any target SOC value, the execution unit can stop charging and keep the secondary battery for a first duration t, then data related to the secondary battery during a charge period and a charge stopping period of the secondary battery is obtained, and the internal resistance of the secondary battery is determined on the basis of the data related to the secondary battery.

Optionally, the apparatus may further include a first determining unit, configured to determine a target SOC value on the basis of an equivalent cycle number of the secondary battery.

The equivalent cycle number N of the secondary battery is determined in one of the following manners:

$$N = \frac{( cumulative charge capacity + cumulative discharge capacity ) / 2}{nominal capacity} , \qquad a 1 )$$

where N is an integer.

In the formula, cumulative charge capacity+cumulative discharge capacity is equal to the total sum of charge capacity and discharge capacity.
b1) N=cumulative charge capacity×h, where h is an ageing coefficient of the secondary battery, 0.75≤h≤0.95, and N is an integer.

When battery cell ageing is taken into account, the ageing coefficient h can be used in this multiplication formula. The ageing coefficient h can be 0.75 to 0.9, where the ageing coefficient of 0.75 corresponds to an SOH of 50%, and the SOH of 50% indicates that the capacity of the battery cell at this moment is 50% of the nominal capacity.

Optionally, a target SOC value may include M target values, and the first determining unit may include:
a calculation subunit, configured to divide the equivalent cycle number N of the secondary battery by M to obtain a remainder R, and determine the target SOC value SOC_{cal} according to the following formula:

$${SOC}_{c a l} = \frac{R}{M} \times 100 \% ;$$

where 2≤M≤50, and M is an integer.

That is, after the first determining unit determines the equivalent cycle number N of the secondary battery, the calculation subunit can calculate a percentage of the ratio of the remainder R obtained by dividing the equivalent cycle number N by the preset value M to M as the target SOC value.

Optionally, the apparatus may further include a second determining unit, configured to determine the target SOC value on the basis of an adjustment coefficient b, where the target SOC value SOC_{cal}∈[SOC_{cal}−b, SOC_{cal}+b], and 0≤b≤10%.

That is, the second determining unit may adjust the target SOC value on the basis of an adjustment coefficient b, and the adjusted SOC value may be used as the final target SOC value.

Optionally, the target SOC value may include 0% and 100%.

Optionally, the internal resistance of the secondary battery may include at least one of a direct current internal resistance R1, an ohmic impedance R2, and a polarization impedance R3.

Optionally, the data related to the second battery may include: a charge current I and a terminal voltage V1 of the secondary battery when the secondary battery stops being charged, and a terminal voltage V0 when the secondary battery stops being charged and is kept for a first duration, where R1=(V1−V0)/I.

Or, the data related to the second battery may include: a charge current I and a terminal voltage V1 of the secondary battery when the secondary battery stops being charged, and a terminal voltage V2 when the secondary battery stops being charged and begins to be polarized, where R2=(V1−V2)/I.

Or, the data related to the secondary battery may include: terminal voltages of the secondary battery corresponding to different moments within the first duration t, an open-circuit voltage of the secondary battery corresponding to the target SOC value, a terminal voltage when the secondary battery stops being charged and begins to be polarized, and the polarization impedance R3 obtained on the basis of a least square method.

Optionally, the apparatus may further include a third determining unit, configured to determine the state of charge (SOC) and/or an SOH of the secondary battery on the basis of internal resistances of the secondary battery corresponding to the different target SOC values.

Optionally, the apparatus may further include a third determining unit, configured to determine a direct current internal resistance increase rate of a battery pack on the basis of internal resistances of the secondary battery corresponding to the different target SOC values, where the direct current internal resistance increase rate of the battery pack is a ratio of a current direct current internal resistance of the battery pack to an initial direct current internal resistance of the battery pack. The battery pack includes a plurality of the secondary batteries, and the initial direct current internal resistance of the battery pack is an average direct current internal resistance of the battery pack after a cycles, where 0≤a≤10.

Optionally, the current direct current internal resistance R1_{pack} of the battery pack meets the following formula:

$$R {1}_{p a c k} = \frac{{\sum }_{i = 1}^{n} R {1}^{′}}{n}$$

where n represents the number of secondary batteries; and R1′ represents an average value of direct current internal resistances corresponding to different target SOC values.

R1′ satisfies the following formula:

$$R {1}^{′} = \frac{{\sum }_{s oc = 0}^{100 \%} R 1}{m}$$

In this formula, m represents the number of different SOC values, and R1 represents direct current internal resistances corresponding to different target SOC values.

According to embodiments of this application, the secondary battery is charged with a charge current, and in response to a real-time state of charge (SOC) of the secondary battery reaching a target SOC value, charging is stopped and the secondary battery is kept for a first duration t; and data related to the secondary battery during a charge period and a charge stopping period of the secondary battery is obtained, and an internal resistance of the secondary battery is determined on the basis of the data related to the secondary battery, where the target SOC value includes a plurality of values. In this way, the direct current internal resistance of the secondary battery can be tested online, so that the accuracy of battery analysis is improved.

Embodiments of this application also provide a battery pack, including a plurality of battery cells and a processor, where the processor detects internal resistances of the battery cells and/or a direct current internal resistance of the battery pack by using the method for detecting an internal resistance of a secondary battery as provided in embodiments of this application.

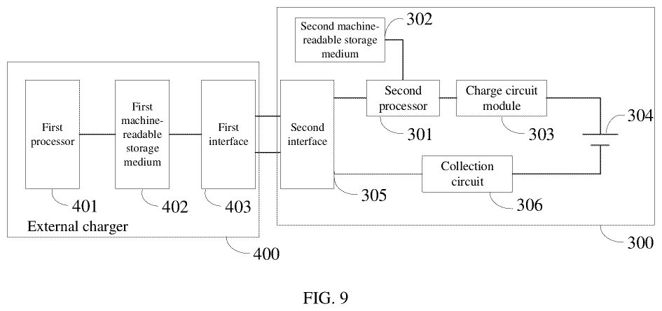

Optionally, the above-mentioned processor may be a microcontroller unit (MCU) on a chip of a battery management system (BMS) in the battery pack. The structure of the BMS of an example may be as shown in FIG. 9. The battery management system 300 includes a second processor 301 and a second machine-readable storage medium 302. The battery management system 300 may also include a charge circuit module 303, a lithium-ion battery 304 (i.e., an electrochemical apparatus), a second interface 305, and a voltage, current and temperature collection circuit 306, where the charge circuit module 303 is configured to receive an instruction given by the second processor 301; and the charge circuit module 303 may also be configured to obtain relevant parameters of the lithium-ion battery 304 (i.e., the electrochemical apparatus) and send the relevant parameters to the second processor 301.

The second interface 305 is configured to be connected with an interface of an external charger 400; the external charger 400 is configured to supply power; the second machine-readable storage medium 302 stores machine-executable instructions that can be executed by a processor, and the second processor 301 is configured to execute the machine-executable instructions.

The external charger 400 may include a first processor 401, a first machine-readable storage medium 402, a first interface 403 and a corresponding rectifying circuit. The external charger may be a commercially available charger, and the structure thereof is not specifically limited in embodiments of this application.

Embodiments of this application further provide a program product. When instructions in the program product are executed by a processor of an electronic device, the electronic device can perform the method for detecting the internal resistance of the secondary battery as provided in the embodiments of this application.

Embodiments of this application further provide an electrical device. The electrical device includes an electrical main body and a battery pack as provided in the embodiments of this application. The battery pack is configured to supply power to the electrical main body.

It is to be understood that this application is not limited to the specific configurations and processes described above and shown in the figures. For the sake of brevity, a detailed description of known methods is omitted herein. In the above embodiments, several specific steps are described and shown as examples. However, the method process of this application is not limited to the specific steps described and shown, and those skilled in the art may make various changes, modifications and additions, or change the order between steps after understanding the spirit of this application.

The functional blocks shown in the above-described block diagram may be implemented as hardware, software, firmware or a combination thereof. When implemented in hardware, the functional blocks may be, e.g., an electronic circuit, an application-specific integrated circuit (ASIC), appropriate firmware, a plug-in, a function card, etc. When implemented in software, elements of this application are programs or code segments that are used to perform a desired task. The program or code segment may be stored in a machine-readable medium or transmitted over a transmission medium or communication link via a data signal carried in a carrier wave. A “machine-readable medium” may include any medium capable of storing or transmitting information. Examples of the machine-readable medium include an electronic circuit, a semiconductor memory apparatus, an ROM, a flash memory, an erasable ROM (EROM), a floppy disk, a CD-ROM, an optical disk, a hard disk, a fiber optic medium, a radio frequency (RF) link, etc. The code segment may be downloaded via a computer network such as the Internet, intranet, etc.

It should also be noted that the exemplary embodiments referred to in this application describe some methods or systems on the basis of a series of steps or apparatuses. However, this application is not limited to the order of the above steps, that is, the steps may be performed in the order mentioned in the embodiment, and may also be performed in the order different from the order in the embodiment, or a plurality of steps may be performed simultaneously.

Various aspects of this application are described above with reference to the flow chart and/or block diagram of the method and apparatus (system) and program product as provided in embodiments of this application. It should be understood that each block in the flow chart and/or block diagram, and combinations of blocks in the flow chart and/or block diagram, can be implemented by program instructions. These program instructions may be provided to a processor of a general purpose computer, a special-purpose computer, or other programmable data processing apparatus to generate a machine such that the instructions executed via the processor of the computer or other programmable data processing apparatus enable the implementation of the functions/actions specified in one or more blocks of the flow chart and/or block diagram. Such a processor may be, but is not limited to, a general purpose processor, a special-purpose processor, an application-specification processor or a field programmable logic circuit. It should also be understood that each block in the block diagram and/or flow chart, and combinations of blocks in the block diagram and/or flow chart, can also be implemented by special-purpose hardware that performs the specified functions or actions, or can be implemented by combinations of special-purpose hardware and computer instructions.

The above description is only specific implementations of this application, and those skilled in the art can clearly understand that for convenience and conciseness of description, the corresponding processes in the aforementioned method embodiments can be referred to for the specific working processes of the above-described systems, modules and units, which will not be repeated herein. It should be understood that the scope of protection of this application is not limited thereto and that various equivalent replacements or modifications are readily contemplated by any person skilled in the art within the scope of the technology disclosed herein, and such replacements or modifications are to be covered within the scope of protection of this application.

What is claimed is:

1. A method for detecting an internal resistance of a secondary battery, the method comprising:
step S1, charging the secondary battery with a charge current, and in response to a real-time state of charge (SOC) of the secondary battery reaching a target SOC value, stopping charging the secondary battery and keeping for a first duration t; and
step S2, obtaining data related to the secondary battery during a charge period and a charge stopping period of the secondary battery, and determining the internal resistance of the secondary battery on the basis of the data related to the secondary battery, wherein
the target SOC value is selected from a plurality of values;
wherein the target SOC value is determined on the basis of an equivalent cycle number of the secondary battery, wherein
the equivalent cycle number N of the secondary battery is determined:
$$N = \frac{( cumulative charge capacity + cumulative discharge capacity ) / 2}{nominal capacity} ,$$
wherein N is an integer,
the target SOC value comprises M target values, dividing the equivalent cycle number N of the secondary battery by M to obtain a remainder R, and determining the target SOC value SOC_{cal} according to the following formula:
$${SOC}_{c a l} = \frac{R}{M} \times 100 \% ,$$
where, 2≤M≤50, and M is an integer.

2. The method according to claim 1, wherein the target SOC value is determined on the basis of an adjustment coefficient b, wherein
the target SOC value SOC_{cal}∈[SOC_{cal}−b, SOC_{cal}+b], and 0≤b≤10%.

3. The method according to claim 1, wherein the internal resistance of the secondary battery comprises at least one of a direct current internal resistance R1, an ohmic impedance R2, or a polarization impedance R3, wherein
the data related to the second battery comprises: a charge current I and a terminal voltage V1 of the secondary battery when the secondary battery stops being charged, and a terminal voltage V0 when the secondary battery stops being charged and is kept for the first duration, wherein
$$R 1 = ( V 1 - V 0 ) / I ,$$
or
the data related to the second battery comprises: a charge current I and a terminal voltage V1 of the secondary battery when the secondary battery stops being charged, and a terminal voltage V2 when the secondary battery stops being charged and begins to be polarized, wherein
$$R 2 = ( V 1 - V 2 ) / I ,$$
or
the data related to the secondary battery comprises: terminal voltages of the secondary battery corresponding to different moments within the first duration t, an open-circuit voltage of the secondary battery corresponding to the target SOC value, a terminal voltage when the secondary battery stops being charged and begins to be polarized, and the polarization impedance R3 obtained on the basis of a least square method.

4. The method according to claim 3, wherein the SOC and/or a state of health (SOH) of the secondary battery is determined on the basis of internal resistances of the secondary battery corresponding to the different target SOC values.

5. The method according to claim 3, wherein a direct current internal resistance increase rate of a battery pack is determined on the basis of internal resistances of the secondary, wherein
the direct current internal resistance increase rate of the battery pack is a ratio of a current direct current internal resistance of the battery pack to an initial direct current internal resistance of the battery pack, and
the battery pack comprises a plurality of the secondary batteries, the initial direct current internal resistance of the battery pack is an average direct current internal resistance of the battery pack after a cycles, and 0≤a≤10.

6. The method according to claim 5, wherein the target SOC value comprises 0% and 100%.

7. The method according to claim 5, wherein the current direct current internal resistance R1_{pack} of the battery pack meets the following formula:
$$R {1}_{p a c k} = \frac{{\sum }_{i = 1}^{n} R {1}^{′}}{n} ,$$
wherein n represents the number of secondary batteries,
where R1′ represents an average value of direct current internal resistances corresponding to different target SOC values, and R1′ satisfies the following formula:
$$R {1}^{′} = \frac{{\sum }_{s oc = 0}^{100 \%} R 1}{m} ,$$
wherein m represents the number of different target SOC values, and R1 represents direct current internal resistances corresponding to different target SOC values.

8. An apparatus for detecting an internal resistance of a secondary battery, comprising:
a control unit, configured to charge the secondary battery with a charge current, and in response to a real-time state of charge (SOC) of the secondary battery reaching a target SOC value, stop charging the secondary battery and keep for a first duration t; and
a calculation unit, configured to obtain data related to the secondary battery during a charge period and a charge stopping period of the secondary battery, and determine an internal resistance of the secondary battery on the basis of the data related to the secondary battery, wherein
the target SOC value comprises a plurality of values;
wherein the target SOC value is determined on the basis of an equivalent cycle number of the secondary battery, wherein
the equivalent cycle number N of the secondary battery is determined:
$$N = \frac{( c u m u l ative charge capacity + cumulative discharge capacity ) / 2}{nominal capacity} ,$$
wherein N is an integer,
the target SOC value comprises M target values, dividing the equivalent cycle number N of the secondary battery by M to obtain a remainder R, and determining the target SOC value SOC_{cal} according to the following formula:
$${SOC}_{c a l} = \frac{R}{M} \times 100 \% ,$$
where, 2≤M≤50, and M is an integer.

9. The apparatus according to claim 8, wherein the target SOC value is determined on the basis of an adjustment coefficient b, wherein
the target SOC value SOC_{cal}∈[SOC_{cal}−b,SOC_{cal}+b], and 0≤b≤10%.

10. The apparatus according to claim 8, wherein the internal resistance of the secondary battery comprises at least one of a direct current internal resistance R1, an ohmic impedance R2, and a polarization impedance R3, wherein
the data related to the second battery comprises: a charge current I and a terminal voltage V1 of the secondary battery when the secondary battery stops being charged, and a terminal voltage V0 when the secondary battery stops being charged and is kept for the first duration, wherein
$$R 1 = ( V 1 - V 0 ) / I ,$$
or
the data related to the second battery comprises: a charge current I and a terminal voltage V1 of the secondary battery when the secondary battery stops being charged, and a terminal voltage V2 when the secondary battery stops being charged and begins to be polarized, wherein
$$R 2 = ( V 1 - V 2 ) / I ,$$
or
the data related to the secondary battery comprises: terminal voltages of the secondary battery corresponding to different moments within the first duration t, an open-circuit voltage of the secondary battery corresponding to the target SOC value, a terminal voltage when the secondary battery stops being charged and begins to be polarized, and the polarization impedance R3 obtained on the basis of a least square method.

11. The apparatus according to claim 10, wherein a direct current internal resistance increase rate of a battery pack is determined on the basis of internal resistances of the secondary, wherein
the direct current internal resistance increase rate of the battery pack is a ratio of a current direct current internal resistance of the battery pack to an initial direct current internal resistance of the battery pack, and
the battery pack comprises a plurality of the secondary batteries, the initial direct current internal resistance of the battery pack is an average direct current internal resistance of the battery pack after a cycles, and 0≤a≤10.

12. The apparatus according to claim 11, wherein the target SOC value comprises 0% and 100%.

13. The apparatus according to claim 10, wherein the current direct current internal resistance R1_{pack} of the battery pack meets the following formula:
$$R {1}_{p a c k} = \frac{{\sum }_{i = 1}^{n} R {1}^{′}}{n} ,$$
wherein n represents the number of secondary batteries,
where R1′ represents an average value of direct current internal resistances corresponding to different target SOC values, and R1′ satisfies the following formula:
$$R {1}^{′} = \frac{{\sum }_{s oc = 0}^{100 \%} R 1}{m} ,$$
wherein m represents the number of different target SOC values, and R1 represents direct current internal resistances corresponding to different target SOC values.

14. A battery pack, comprising a plurality of battery cells and a processor, wherein the processor detects internal resistances of the battery cells and/or a direct current internal resistance of the battery pack by using the method for detecting an internal resistance of a secondary battery according to claim 1.

15. The battery pack according to claim 14, wherein the target SOC value is determined on the basis of an adjustment coefficient b, wherein
the target SOC value SOC_{cal}∈[SOC_{cal}−b, SOC_{cal}+b], and 0≤b≤10%.

16. The battery pack according to claim 14, wherein the internal resistance of the secondary battery comprises at least one of a direct current internal resistance R1, an ohmic impedance R2, and a polarization impedance R3, wherein
the data related to the second battery comprises: a charge current I and a terminal voltage V1 of the secondary battery when the secondary battery stops being charged, and a terminal voltage V0 when the secondary battery stops being charged and is kept for the first duration, wherein
$$R 1 = ( V 1 - V 0 ) / I ,$$
or
the data related to the second battery comprises: a charge current I and a terminal voltage V1 of the secondary battery when the secondary battery stops being charged, and a terminal voltage V2 when the secondary battery stops being charged and begins to be polarized, wherein
$$R 2 = ( V 1 - V 2 ) / I ,$$
or
the data related to the secondary battery comprises: terminal voltages of the secondary battery corresponding to different moments within the first duration t, an open-circuit voltage of the secondary battery corresponding to the target SOC value, a terminal voltage when the secondary battery stops being charged and begins to be polarized, and the polarization impedance R3 obtained on the basis of a least square method.

17. The battery pack according to claim 16, wherein a direct current internal resistance increase rate of a battery pack is determined on the basis of internal resistances of the secondary, wherein
the direct current internal resistance increase rate of the battery pack is a ratio of a current direct current internal resistance of the battery pack to an initial direct current internal resistance of the battery pack, and
the battery pack comprises a plurality of the secondary batteries, the initial direct current internal resistance of the battery pack is an average direct current internal resistance of the battery pack after a cycles, and 0≤a≤10.

18. The battery pack according to claim 17, wherein the target SOC value comprises 0% and 100%.

19. The battery pack according to claim 16, wherein the current direct current internal resistance R1_{pack} of the battery pack meets the following formula:
$$R {1}_{p a c k} = \frac{{\sum }_{i = 1}^{n} R {1}^{′}}{n} ,$$
wherein n represents the number of secondary batteries,
where R1′ represents an average value of direct current internal resistances corresponding to different target SOC values, and R1′ satisfies the following formula:
$$R {1}^{′} = \frac{{\sum }_{s oc = 0}^{100 \%} R 1}{m} ,$$
wherein m represents the number of different target SOC values, and R1 represents direct current internal resistances corresponding to different target SOC values.
